(19) United States
(12) Patent Application Publication
(10) Pub. No.: US 2001/0011777 A1
(43) Pub. Date: Aug. 9, 2001

(54) Semiconductor device using a BGA package and method of producing the same

(76) Inventor: Hideki Kano, Tokyo (JP)

Correspondence Address: HELFGOTT & KARAS P.C., 60th Floor, Empire State Building, New York, NY, 10118-0110, US

(21) Appl. No.: 09/779,762

(22) Filed: Feb. 8, 2001

(30) Foreign Application Priority Data
Feb. 9, 2000 (JP) 31710/2000

(51) Int. Cl. H01L 23/48; H01L 21/44; H01L 21/48; H01L 21/50

(52) U.S. Cl. 257/781; 438/110; 438/612

(57) ABSTRACT

A BGA type semiconductor device includes a base member 1, a land portion 2 formed on the base member 1, and a plurality of protrusions 4 formed on the land portion 2 by plating. Through the protrusions 4, the land portion 2 is connected to a solder ball 6. Each of the land portion 2 and the protrusions 4 has a surface coated with a metal plating layer 5.

### BACKGROUND OF THE INVENTION

This invention relates to a semiconductor device using a BGA (Ball Grid Array) package and a method of producing the same.

In a BGA (Ball Grid Array) package, a solder ball is reduced in diameter following the increase in number of pins and the reduction in size of an LSI (Large Scale Integrated circuit).

The BGA package is often used in a mobile apparatus and may be subjected to the shock of a fall. Therefore, it is important to increase the strength of connection between the solder ball and a base member.

In a conventional BGA type semiconductor device, a solder ball 44 is connected to a land portion 42 which is formed on a base member 41 and has a flat structure, as illustrated in FIG. 1. A metal plating layer 45 is formed on the land portion 42. The base member 41 is provided with a solder resist 43 which is in contact with the land portion 42. The solder ball 44 is in contact with the solder resist 43. With this structure, a connection area where the solder ball 44 and the base member 41 are connected to each other is insufficiently small. Therefore, the solder ball 44 may often fall down or may be detached from the base member 41 in a thermal shock test. This leads to an open-circuited condition.

In order to remove the above-mentioned problem, Japanese Unexamined Patent Publication (A) No. H11-40940 proposes a BGA type semiconductor device having a structure intended to improve the strength of connection. The BGA type semiconductor device is illustrated in FIG. 2A. In FIG. 2A, the land portion 42 on the base member 41 is etched to form a plurality of recesses 56. Thus, a connection area between a solder ball 54 and the land portion 42 is enlarged.

However, the above-mentioned structure is disadvantageous in the following respects which will presently be described in conjunction with FIG. 2B together with FIG. 2A.

The first disadvantage is as follows. In the structure obtained by etching the land portion 42, it is often that the recesses 56 formed in the land portion 42 are not completely filled with a molten solder 57 to leave gaps 58. In this event, when the LSI is mounted on a printed wiring board (PWB), various defects 59 such as cracks and blistering are produced from the gaps 58 under a thermal stress.

The second disadvantage is as follows. When the land portion 42 is etched, the surface of the land portion 42 may be contaminated or oxidized. This prevents formation of the plating layer 45 on the surface of the land portion 42 in a good and sufficient condition so that the contact between the solder ball 54 and the land portion 42 is deteriorated.

### SUMMARY OF THE INVENTION

It is therefore an object of this invention to improve the strength of connection between a land portion and a solder ball in a BGA type semiconductor device and a method of producing the same.

It is another object of this invention to prevent the formation of a gap between a solder ball and a land portion in a BGA type semiconductor device and a method of producing the same.

It is still another object of this invention to keep the cleanness of the surface of a land portion in a BGA type semiconductor device and a method of producing the same.

According to this invention, there is provided a BGA (Ball Grid Array) type semiconductor device comprising:

a land portion formed on a base member; and

a plurality of protrusions formed on the land portion.

The BGA type semiconductor device further comprises a solder ball to which the land portion is connected through the protrusions formed on the land portion.

The protrusions are formed so that a connection area between the land portion and the solder ball is enlarged.

Each of the land portion and the protrusions has a surface coated with a metal plating layer.

The land portion and the solder ball are connected through the metal plating layer formed on the surface of each of the land portion and the protrusions.

Preferably, the base member is a printed board or a tape.

Preferably, the land portion is made of a metal. Preferably, the metal is copper (Cu).

Preferably, the protrusions are made of copper (Cu).

The protrusions are formed on the surface of the land portion without etching the land portion.

The base member is provided with a solder resist in contact with the land portion. Each of the protrusions is located to be in contact with a side surface of the solder resist.

Preferably, the protrusions have a height substantially equal to the thickness of the solder resist.

According to this invention, there is also provided a method of producing a BGA type semiconductor device, comprising the steps of:

forming a land portion on a base member;

applying a resist to cover the land portion;

selectively removing a plurality of portions of the resist to expose a plurality of parts of the land portion;

carrying out metal plating on the land portion to form a plurality of metal plating portions on the plurality of parts of the land portion; and

removing a remaining portion of the resist to leave the plurality of metal plating portions protruding as a plurality of protrusions on the land portion.

The method further comprises the steps of:

applying a solder resist to cover the base member and the land portion;

forming an opening portion in the solder resist to expose the plurality of protrusions and a central part of the land portion which central part surrounds the plurality of protrusions;

forming a metal plating layer on the plurality of protrusions and the central part of the land portion; and

connecting, by fusion-bonding, a solder ball to the land portion through the plurality of protrusions formed on the land portion.

The plurality of protrusions are formed on the land portion without etching the land portion.

In the semiconductor device using a BGA package according to this invention, the projections are formed on the land portion (to be connected to the solder ball) formed on the base member such as a tape and a printed board to thereby enlarge the connection area where the solder ball and the land portion are connected to each other.

More specifically, since the protrusions are formed on the land portion, the connection area is increased as compared with the conventional BGA type semiconductor device in which the land portion has a flat structure (see FIG. 1). As a consequence, the strength of connection between the land portion and the solder ball is improved.

In the conventional BGA type semiconductor device intended to increase the strength of connection between the land portion and the solder ball, the land portion is etched to form the recesses so that the connection area is enlarged (see FIGS. 2A and 2B). However, this structure is disadvantageous in that, upon connection of the solder ball, the molten solder may not completely be filled in the recesses to leave the gaps. These gaps may cause cracks at a high temperature when the BGA package is mounted on the printed board. On the other hand, it is possible according to this invention to avoid the formation of such gaps between the solder ball and the land portion.

In the structure illustrated in FIGS. 2A and 2B, the land portion is etched. Therefore, the surface of the land portion may be contaminated and an etch residue or other foreign matters may be caught upon etching. On the other hand, it is possible according to this invention to keep the cleanness of the surface of the land portion because the protrusions are formed by plating.

### BRIEF DESCRIPTION OF THE DRAWING

FIG. 1 shows a conventional BGA type semiconductor device having a land of a flat structure;

FIGS. 2A and 2B show another conventional BGA type semiconductor device having a land of a recessed structure;

FIG. 3 shows a BGA type semiconductor device according to a first embodiment of this invention;

FIGS. 4A through 4H are views for describing a method of producing the BGA type semiconductor device illustrated in FIG. 3; and

FIGS. 5A and 5B show a BGA type semiconductor device according to a second embodiment of this invention.

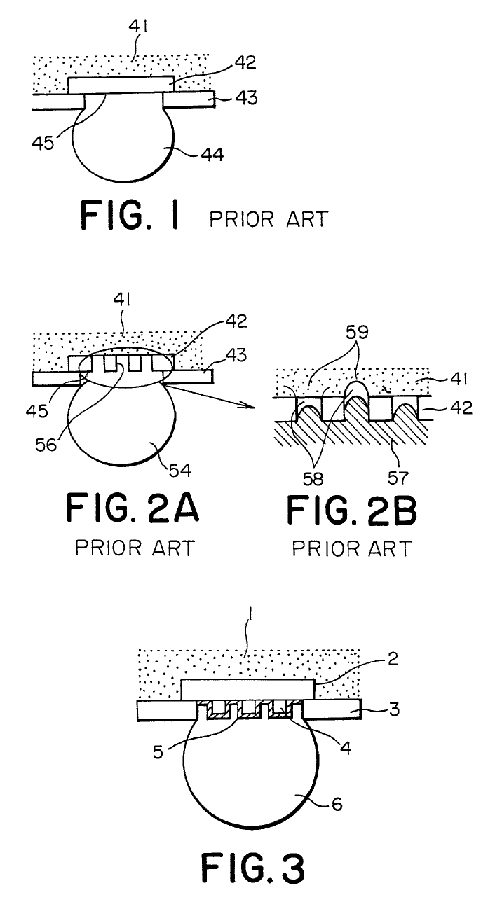

### DESCRIPTION OF THE PREFERRED EMBODIMENTS

First Embodiment

Referring to FIG. 3, description will be made of a BGA type semiconductor device according to a first embodiment of this invention.

The BGA type semiconductor device illustrated in FIG. 3 includes a base member 1 comprising a substrate or a tape, a land portion (to be connected to a solder ball) 2 made of a metal such as copper (Cu), and a solder resist 3 for protection and insulation of the base member 1.

On the land portion 2, a plurality of protrusions 4 are formed, for example, by Cu plating. Each of the land portion 2 and the protrusions 4 has a surface coated with a metal plating layer 5.

With the above-mentioned structure, a solder ball 6 is connected to the surface of the metal plating layer 5.

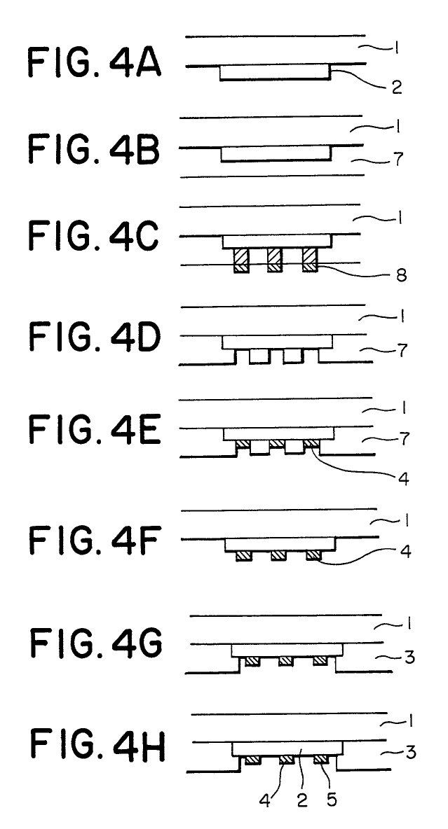

Next referring to FIGS. 4A through 4H, description will be made of a method of producing the BGA type semiconductor device illustrated in FIG. 3. The illustrated method is a protrusion forming process.

At first referring to FIG. 4A, the base member 1 is subjected to circuit formation to form the land portion 2. Herein, the land portion 2 has a height of about 30 μm.

Next referring to FIG. 4B, a solder resist 7 for Cu plating is applied.

As illustrated in FIG. 4C, the solder resist 7 is partially covered with a mask 8 at positions corresponding to the protrusions 4. Then, exposure and development are carried out.

Referring to FIG. 4D, the mask 8 and a part of the solder resist 7 at the positions corresponding to the protrusions 4 are removed.

As illustrated in FIG. 4E, the protrusions 4 are formed by metal plating. Herein, the metal plating is Cu plating. The protrusions have a height between about 25 and 30 μm.

Referring to FIG. 4F, the solder resist 7 for Cu plating is removed.

Thereafter, the solder resist 3 is applied and a part of the solder resist 3 at an opening portion are removed as illustrated in FIG. 4G.

Next referring to FIG. 4H, the metal plating layer 5 such as Ni and Au is formed on the land portion 2 and the protrusions 4.

Finally, as illustrated in FIG. 3, the solder ball 6 is melted at a temperature of 200° C. or more and connected to the protrusions 4 through the metal plating layer 5 formed in the step illustrated in FIG. 4H.

Second Embodiment

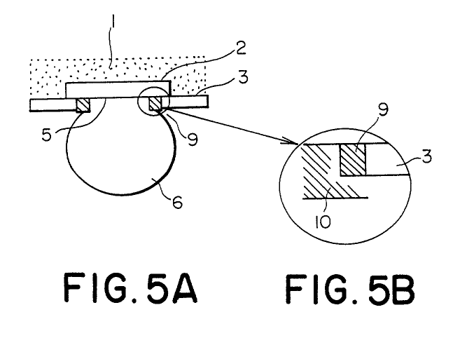

Next, description will be made of a BGA type semiconductor device according to a second embodiment of this invention with reference to FIGS. 5A and 5B.

A plurality of protrusions 9 are formed in a manner similar to that described in conjunction with FIGS. 4A through 4H.

In the second embodiment, the protrusions 9 are located to be in contact with side surfaces of the solder resist 3, as illustrated in FIG. 5A.

With this structure, when a solder 10 is melted at the high temperature to connect the solder ball 6, the solder ball 6 is soldered not only towards the land portion 2 but also towards the side surfaces of the solder resist 3, as illustrated in FIG. 5B. Thus, the connection area is enlarged.

As a consequence, the strength of connection is further improved. In this case, the protrusions 9 have a height of about 30 μm substantially equal to the thickness of the solder resist 3.

A first effect of this invention is an improvement in strength of connection between the land portion and the solder ball. This is because the protrusions formed on the land portion enlarge the connection area as compared with the flat structure in the conventional BGA type semiconductor device.

A second effect of this invention is to prevent the formation of gaps between the solder ball and the land portions. In the conventional BGA type semiconductor device intended to increase the strength of connection between the land portion and the solder ball, the land portion is etched to form the recesses so that the connection area is enlarged.

However, this structure is disadvantageous in that, upon connection of the solder ball, the molten solder may not completely be filled in the recesses to leave the gaps. These gaps may cause cracks at a high temperature when the BGA package is mounted on the printed board. According to this invention, occurrence of cracks due to presence of such gaps can be avoided.

A third effect of this invention is to keep the cleanness of the surface of the land portion. In the conventional structure referred to in connection with the second effect, the land portion is etched. Therefore, the surface of the land portion may be contaminated and an etch residue or other foreign matters may be caught upon etching. On the other hand, according to this invention, the surface of the land portion is kept at a high cleanness because the protrusions are formed by plating.

What is claimed is:

1. A BGA (Ball Grid Array) type semiconductor device comprising:
a land portion formed on a base member; and
a plurality of protrusions formed on said land portion.

2. A BGA type semiconductor device as claimed in claim 1, further comprising a solder ball to which said land portion is connected through said protrusions formed on said land portion.

3. A BGA type semiconductor device as claimed in claim 2, wherein said protrusions are formed so that a connection area between said land portion and said solder ball is enlarged.

4. A BGA type semiconductor device as claimed in claim 2, wherein each of said land portion and said protrusions has a surface coated with a metal plating layer.

5. A BGA type semiconductor device as claimed in claim 4, wherein said land portion and said solder ball are connected through said metal plating layer formed on the surface of each of said land portion and said protrusions.

6. A BGA type semiconductor device as claimed in claim 1, wherein said base member is a printed board or a tape.

7. A BGA type semiconductor device as claimed in claim 1, wherein said land portion is made of a metal.

8. A BGA type semiconductor device as claimed in claim 7, wherein said metal is copper (Cu).

9. A BGA type semiconductor device as claimed in claim 1, wherein said protrusions are made of copper (Cu).

10. A BGA type semiconductor device as claimed in claim 1 wherein said protrusions are formed on the surface of said land portion without etching said land portion.

11. A BGA type semiconductor device as claimed in claim 1, wherein said base member is provided with a solder resist in contact with said land portion, each of said protrusions being located to be in contact with a side surface of said solder resist.

12. A BGA type semiconductor device as claimed in claim 1, wherein said protrusions have a height substantially equal to the thickness of said solder resist.

13. A method of producing a BGA type semiconductor device, comprising the steps of:
forming a land portion on a base member;
applying a resist to cover said land portion;
selectively removing a plurality of portions of said resist to expose a plurality of parts of said land portion;
carrying out metal plating on said land portion to form a plurality of metal plating portions on said plurality of parts of the land portion; and
removing a remaining portion of said resist to leave said plurality of metal plating portions protruding as a plurality of protrusions on said land portion.

14. A method as claimed in claim 13, further comprising the steps of:
applying a solder resist to cover said base member and said land portion;
forming an opening portion in said solder resist to expose said plurality of protrusions and a central part of said land portion which central part surrounds said plurality of protrusions;
forming a metal plating layer on said plurality of protrusions and said central part of the land portion; and
connecting, by fusion-bonding, a solder ball to said land portion through said plurality of protrusions formed on said land portion.

15. A method as claimed in claim 13, wherein said plurality of protrusions are formed on said land portion without etching said land portion.
